(19) United States
(12) Patent Application Publication
(10) Pub. No.: US 2023/0187463 A1
(43) Pub. Date: Jun. 15, 2023

(54) IMAGE SENSOR SUBSTRATE AND IMAGE SENSOR INCLUDING THE SAME

(71) Applicant: Samsung Electronics Co., Ltd., Suwon-si (KR)

(72) Inventors: Hye Yun Park, Hwaseong-si (KR); Yeon Sook Kim, Hwaseong-si (KR); In Ji Lee, Hwaseong-si (KR); Tae Young Song, Hwaseong-si (KR)

(21) Appl. No.: 18/060,180

(22) Filed: Nov. 30, 2022

(30) Foreign Application Priority Data
Dec. 10, 2021 (KR) 10-2021-0176547

(51) Int. Cl. H01L 27/146

(52) U.S. Cl. CPC H01L 27/1463; H01L 27/14627; H01L 27/14636; H01L 27/14689

(57) ABSTRACT

An image sensor substrate includes a semiconductor substrate layer and a semiconductor epitaxial layer on the substrate layer. The semiconductor substrate layer has a boron (B) doping concentration therein in a range from 3×10¹⁸ cm⁻³ to 1×10¹⁹ cm⁻³, whereas the semiconductor epitaxial layer has a boron (B) doping concentration therein in a range from 1×10¹⁶ cm⁻³ to 6×10¹⁶ cm⁻³.

### REFERENCE TO PRIORITY APPLICATION

This application claims priority under 35 U.S.C. 119 to Korean Patent Application No. 10-2021-0176547, filed Dec. 10, 2021, the disclosure of which is hereby incorporated herein by reference.

### BACKGROUND

### 1. Technical Field

The present disclosure relates to integrated circuit devices and, more particularly, to image sensor devices and components thereof including image sensor substrates.

### 2. Description of the Related Art

For wafers used in image sensors, p-type and n-type substrates are used according to product requirements. In addition, there may be a case where the wafer used in the image sensor uses only the substrate, or may be a case where the wafer uses the substrate having an epitaxial layer deposited thereon.

Meanwhile, in order to separate a metallic contamination source that may affects the performance of the image sensor into an area other than the element operation area, the role of a gettering sink should be strengthened. In the case of a substrate having a high boron concentration (heavily-boron doped), the generation of a bond between boron (B) and oxygen (O) by boron promotes the generation of BMD, so that the metallic contamination source may be gettered. In addition, iron (Fe) impurities are bound to iron (Fe) and boron (B) due to a separation phenomenon caused by a difference in solubility, and the metallic contamination source may be strongly gettered by the iron-boron bond. Accordingly, as the concentration of boron (B) contained in the substrate is increased, it is advantageous for gettering of the metallic contamination source.

In addition, to reduce crosstalk between the photoelectric conversion regions of the image sensor, the photoelectric conversion regions may be insulated from each other using a pixel isolation pattern. In this case, an ion implantation process for implanting boron (B) into the sidewall of the pixel isolation pattern may be required. Due to the ion implantation process, boron may be diffused toward each photoelectric conversion region through the sidewall of the pixel isolation pattern. As the size of the pixel decreases, the concentration of boron in the central portions of the photoelectric conversion regions may increase, and thus the performance of the image sensor may deteriorate.

### SUMMARY

Aspects of the present disclosure provide an enhanced substrate for manufacturing an image sensor, in order to manufacture an image sensor with improved performance and reliability.

Aspects of the present disclosure may also provide an image sensor with improved performance and reliability.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is provided a substrate for manufacturing an image sensor. This substrate includes a substrate layer, and an epitaxial layer on the substrate layer. A concentration of boron (B) in the substrate layer is in a range from 3×10¹⁸ atoms/cm³ to 1×10¹⁹ atoms/cm³, and a concentration of boron (B) in the epitaxial layer is in a range from 1×10¹⁶ atoms/cm³ to 6×10¹⁶ atoms/cm³.

According to another aspect of the present disclosure, there is provided an image sensor having a first substrate therein, which includes first and second opposing surfaces. A plurality of unit pixels are provided in the first substrate. Each unit pixels includes a photoelectric conversion region, a floating diffusion region, and a transfer transistor electrically connecting the photoelectric conversion region to the floating diffusion region. A pixel isolation pattern is provided, which at least partially penetrates the first substrate and defines each of the unit pixels. A microlens is provided, which extends on the second surface of the first substrate. A second substrate is provided, which extends on the first surface of the first substrate, and includes a fourth surface facing the first surface and a third surface opposing the fourth surface. The second substrate includes a source follower transistor, a select transistor, and a reset transistor having terminals electrically connected to the floating diffusion region, on the fourth surface of the second substrate. Advantageously, a concentration of boron (B) in the first substrate is in a range from 1×10¹⁶ atoms/cm³ to 6×10¹⁶ atoms/cm³.

According to another aspect of the present disclosure, an image sensor is provided that includes a first substrate having first and second opposing surfaces thereon, and a plurality of unit pixels in the first substrate. Each unit pixel includes a photoelectric conversion layer, a floating diffusion region, and a transfer transistor electrically connecting the photoelectric conversion layer to the floating diffusion region. A pixel isolation pattern is provided, which at least partially penetrates the first substrate and defines the lateral dimensions of the unit pixels. A microlens is provided on the second surface of the first substrate, and a second substrate is provided on the first surface of the first substrate. The second substrate includes a fourth surface that faces the first surface and a third surface extending opposite the fourth surface. A source follower transistor, a select transistor, and a reset transistor, which are electrically connected to the floating diffusion region, are provided adjacent the fourth surface of the second substrate. A third substrate may be provided on the third surface of the second substrate, and a plurality of logic circuits may be provided in the third substrate. These logic circuits may be configured to control the source follower transistor, the select transistor, and the reset transistor. Advantageously, a concentration of boron (B) in the first substrate is in a range from 4×10¹⁶ atoms/cm³ to 5.5×10¹⁶ atoms/cm³, and this concentration is substantially uniform in a region extending from a sidewall of the pixel isolation pattern toward the photoelectric conversion layer.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is an exemplary view for explaining a substrate for manufacturing an image sensor according to some embodiments.

FIG. 2 is an exemplary graph for explaining the performance of a substrate for manufacturing an image sensor according to some embodiments.

FIG. 3 is an exemplary graph for explaining the performance of a substrate for manufacturing an image sensor according to some embodiments.

FIG. 4 is an exemplary block diagram of an image sensor according to some embodiments.

FIG. 5 is a block diagram illustrating the first pixel array, the second pixel array, the logic circuit, and the ADC of FIG. 4.

FIG. 6 is a circuit diagram for describing a unit pixel of the first pixel array and the second pixel array of FIG. 4.

FIG. 7 is a perspective exploded view for three-dimensionally demonstrating the first pixel array, the second pixel array, the logic circuit, and the ADC of the image sensor of FIG. 4.

FIG. 8 is an exemplary cross-sectional view of the image sensor of FIG. 7.

FIG. 9 is an enlarged view of area P of FIG. 8.

FIGS. 10A and 10B are graphs illustrating the concentration of boron included in the first substrate in a cross section taken along line A-A′ of FIG. 9.

FIG. 11 is a cross-sectional view of an image sensor according to some embodiments.

FIG. 12 is a cross-sectional view of an image sensor according to some embodiments.

FIG. 13 is a perspective view for three-dimensionally explaining an image sensor according to some embodiments.

FIGS. 14 to 20 are cross-sectional views of intermediate structures that illustrate methods of manufacturing an image sensor according to some embodiments.

### DETAILED DESCRIPTION OF THE EMBODIMENTS

Hereinafter, inventive aspects according to some embodiments of the present disclosure will be described in more detail with reference to the accompanying drawings.

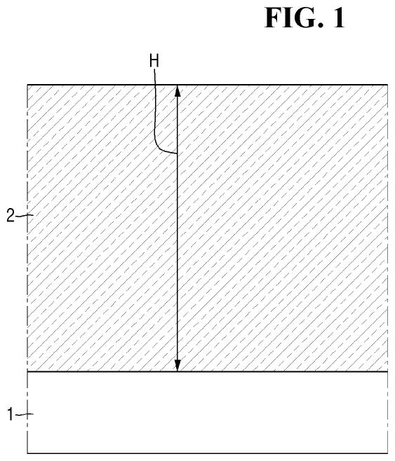

For example, a substrate for manufacturing an image sensor according to some embodiments will be described with reference to FIGS. 1 to 3, where FIG. 1 is an exemplary view for explaining a substrate for manufacturing an image sensor according to some embodiments.

Referring to FIG. 1, a substrate for manufacturing an image sensor according to some embodiments may include a substrate layer 1 and an epitaxial layer 2 on the substrate layer 1. The substrate layer 1 may be a semiconductor substrate, and may be a base substrate. For example, the substrate layer 1 may be a silicon substrate, or may include other materials, such as: silicon germanium, indium antimonide, lead tellurium compound, indium arsenide, indium phosphide, gallium arsenide, or gallium antimonide.

The epitaxial layer 2 may be provided on the substrate layer 1. The epitaxial layer 2 may be formed by epitaxial growth, by using the substrate layer 1 as a base substrate (“seed”), but is not limited thereto.

The substrate layer 1 may be a substrate doped with boron (B), and the epitaxial layer 2 may be an epitaxial layer doped with boron (B). The concentration of boron (B) included in the substrate layer 1 is preferably higher than the concentration of boron (B) included in the epitaxial layer 2. For example, in some embodiments, the concentration of boron (B) included in the substrate layer 1 may be 50 (or more) times higher than the concentration of boron (B) included in the epitaxial layer 2.

In some embodiments, the substrate layer 1 may include a gettering sink, and the gettering sink may be formed at an optional position in the substrate layer 1, but is not limited thereto. During a process of manufacturing the image sensor according to some embodiments, metal may penetrate into the substrate layer 1. When metal penetrates into the substrate layer 1, crystal defects due to the metal may occur. A white spot and an energy level in the band gap may be formed by the crystal defect. In order to suppress such image defects, metal that has penetrated into the semiconductor layer should be gettered, and a space/region in which the metal is gettered may be treated as a gettering sink.

The concentration of boron (B) included in the substrate layer 1 may be in a range from 1×10¹⁹ atoms/cm³ or less, such as in a range from 3×10¹⁸ atoms/cm³ to 1×10¹⁹ atoms/cm³. Preferably, the concentration of boron (B) contained in the substrate layer 1 may be in a range from 3×10¹⁸ atoms/cm³ to 5×10¹⁸ atoms/cm³.

In contrast, the concentration of boron (B) included in the epitaxial layer 2 may be in a substantially lower range from 1×10¹⁶ atoms/cm³ to 6×10¹⁶ atoms/cm³. More preferably, the concentration of boron (B) included in the epitaxial layer 2 may be in a range from 4×10¹⁶ atoms/cm³ to 5.5×10¹⁶ atoms/cm³, including 5×10¹⁶ atoms/cm³, which may be more preferred in some embodiments.

Moreover, when the concentration of boron (B) included in the substrate layer 1 and the concentration of boron (B) included in the epitaxial layer 2 are at the above concentrations, then, in some embodiments of manufacturing an image sensor, a plasma doping ion implantation (PLAD) process may be omitted without diminishing image sensor performance.

In some additional embodiments, a thickness H of the epitaxial layer 2 may be 10 μm or more. The thickness H of the epitaxial layer 2 may correspond to a height in a vertical direction from the top surface of the substrate layer 1 to the top surface of the epitaxial layer 2. When the substrate layer 1 is used as the base substrate, the thickness H of the epitaxial layer 2 may be 10 μm or more; however, the present disclosure is not limited thereto.

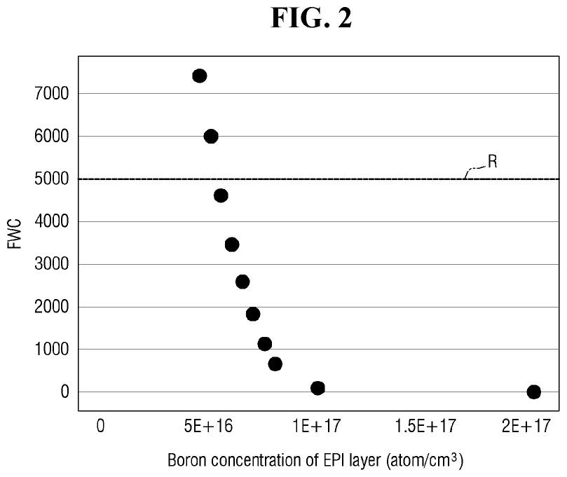

FIG. 2 is an exemplary graph for explaining the performance of a substrate for manufacturing an image sensor according to some embodiments. For reference, the x-axis of FIG. 2 may be the concentration of boron (B) included in the epitaxial layer 2, and the y-axis may be the full well capacity (FWC) of a photoelectric conversion layer (photodiode) of an image sensor according to some embodiments. The full well capacity (FWC) may mean the maximum amount of signal electrons that the photoelectric conversion layer of one unit pixel may contain.

Referring to FIG. 2, a reference line R denotes a full well capacity (FWC) of a photoelectric conversion layer of an image sensor in related art. The full well capacity (FWC) of the photoelectric conversion layer of the image sensor in related art may be about 5000 ea, where the FWC is defined as the amount of charge (i.e., photoelectrons) that can be stored within an individual pixel without the pixel becoming saturated. As shown, when the concentration of boron (B) contained in the epitaxial layer 2 is about 1×10¹⁶ atoms/cm³ or more and 6×10¹⁶ atoms/cm³ or less, the full well capacity (FWC) of the photoelectric conversion layer may be about 4500 ea to 9000 ea. When the concentration of boron (B) included in the epitaxial layer 2 is 5×10¹⁶ atoms/cm³, the full well capacity (FWC) of the photoelectric conversion layer may be about 6000 ea. That is, when the image sensor is manufactured by using the substrate for manufacturing an image sensor according to some embodiments, the performance similar to that of the image sensor in related art may be obtained even omitting the plasma doping ion implantation (PLAD) process.

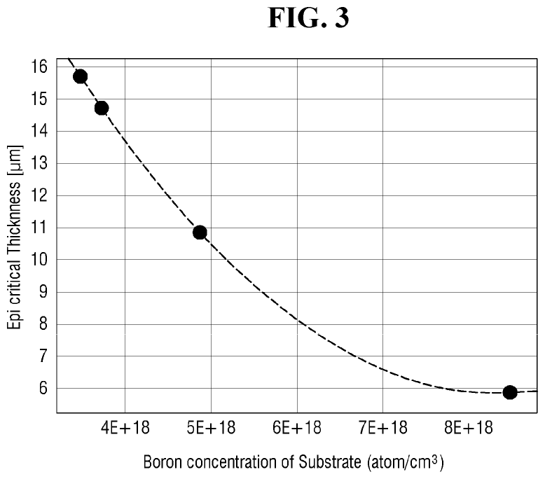

FIG. 3 is an exemplary graph for explaining the performance of a substrate for manufacturing an image sensor according to some embodiments. For reference, the x-axis of FIG. 3 may be the concentration of boron (B) included in the substrate layer 1, and the y-axis may be the critical thickness of the epitaxial layer 2. The critical thickness may mean a thickness of the epitaxial layer 2 when the epitaxial layer 2 is grown directly from the substrate layer 1, which operates as a base substrate (i.e., “seed”).

Referring to FIG. 3, when the concentration of boron (B) contained in the substrate layer 1 is 3×10¹⁸ atoms/cm³ or more and 5×10¹⁸ atoms/cm³ or less, the critical thickness of the epitaxial layer 2 may be about 10 μm or more. For example, when the concentration of boron (B) included in the substrate layer 1 is 3×10¹⁸ atoms/cm³, the critical thickness of the epitaxial layer 2 may be about 16 μm. When the concentration of boron (B) included in the substrate layer 1 is 5×10¹⁸ atoms/cm³, the critical thickness of the epitaxial layer 2 may be about 10 μm.

As the critical thickness of the epitaxial layer 2 is secured to be 10 μm or more, the depth of the photoelectric conversion layer of the image sensor manufactured using the substrate for manufacturing an image sensor according to some embodiments may also be secured to be 10 μm or more.

Hereinafter, the performance of an image sensor manufactured using the substrate for manufacturing an image sensor according to some embodiments will be described with reference to embodiments and Comparative Examples of the present disclosure.

Table 1 illustrates the results of measuring the full well capacity (FWC) of the Experimental Example in related art, Comparative Example 1, Comparative Example 2, Comparative Example 3, Embodiment 1, Embodiment 2, and Embodiment 3.

TABLE 1

| | Concentration of | | |
|---|---|---|---|
| | Epitaxial Layer | PLAD | Full Well |
| | (atoms/cm³) | Process | Capacity (ea) |
| Related Art | 4.44 × 10¹⁴ | Performed | 5081 |
| Comparative | 5.00 × 10¹⁶ | | 493 |
| Example 1 | | | |
| Comparative | 5.50 × 10¹⁶ | | 366 |
| Example 2 | | | |
| Comparative | 4.44 × 10¹⁴ | Not | 12982 |
| Example 3 | | performed | |
| Embodiment 1 | 4.00 × 10¹⁶ | | 8746 |
| Embodiment 2 | 5.00 × 10¹⁶ | | 5999 |
| Embodiment 3 | 5.50 × 10¹⁶ | | 4620 |

### Experimental Example in Related Art

The experimental example in related art illustrates the full well capacity (FWC) of the photoelectric conversion layer when the PLAD process is performed in the image sensor in related art. The concentration of the epitaxial layer of the image sensor in related art may be about 4.44×10¹⁴ atoms/cm³. When the concentration of the epitaxial layer is 4.44×10¹⁴ atoms/cm³, the full well capacity of the photoelectric conversion layer when the PLAD process is performed may be 5081 ea.

### Comparative Example 1

Comparative Example 1 illustrates the full well capacity of the photoelectric conversion layer when the PLAD process is performed when the concentration of the epitaxial layer is 5.00×10¹⁶ atoms/cm³. When the concentration of the epitaxial layer is 5.00×10¹⁶ atoms/cm³, the full well capacity of the photoelectric conversion layer when the PLAD process is performed may be 493 ea.

### Comparative Example 2

Comparative Example 2 illustrates the full well capacity of the photoelectric conversion layer when the PLAD process is performed when the concentration of the epitaxial layer is 5.50×10¹⁶ atoms/cm³. When the concentration of the epitaxial layer is 5.50×10¹⁶ atoms/cm³, the full well capacity of the photoelectric conversion layer when the PLAD process is performed may be 366 ea.

### Comparative Example 3

Comparative Example 3 illustrates the full well capacity of the photoelectric conversion layer when the PLAD process is not performed when the concentration of the epitaxial layer is 4.44×10¹⁴ atoms/cm³. When the concentration of the epitaxial layer is 4.44×10¹⁴ atoms/cm³, the full well capacity of the photoelectric conversion layer when the PLAD process is not performed may be 12982 ea.

### Embodiment 1

Embodiment 1 illustrates the full well capacity of the photoelectric conversion layer when the PLAD process is not performed when the concentration of the epitaxial layer is 4.00×10¹⁶ atoms/cm³. When the concentration of the epitaxial layer is 4.00×10¹⁶ atoms/cm³, the full well capacity of the photoelectric conversion layer when the PLAD process is not performed may be 8746 ea.

### Embodiment 2

Embodiment 2 illustrates the full well capacity of the photoelectric conversion layer when the PLAD process is not performed when the concentration of the epitaxial layer is 5.00×10¹⁶ atoms/cm³. When the concentration of the epitaxial layer is 5.00×10¹⁶ atoms/cm³, the full well capacity of the photoelectric conversion layer when the PLAD process is not performed may be 5999 ea.

### Embodiment 3

Embodiment 3 illustrates the full well capacity of the photoelectric conversion layer when the PLAD process is not performed when the concentration of the epitaxial layer is 5.50×10¹⁶ atoms/cm³. When the concentration of the epitaxial layer is 5.50×10¹⁶ atoms/cm³, the full well capacity of the photoelectric conversion layer when the PLAD process is not performed may be 4620 ea.

Referring to Table 1, Embodiment 1 through Embodiment 3 have values similar to the full well capacity of the photoelectric conversion layer of the image sensor in related art. On the other hand, Comparative Examples 1 and 2 have the full well capacity that is significantly smaller than the full well capacity of the photoelectric conversion layer of the image sensor in related art. In addition, Comparative Example 3 has a full well capacity significantly larger than the full well capacity of a photoelectric conversion layer of an image sensor in related art.

This may be interpreted that Embodiment 1 to Embodiment 3 have similar performance to the image sensor in related art even though the PLAD process is omitted. That is, when the concentration of the epitaxial layer 2 is 4.00×10¹⁶ atoms/cm³, 5.00×10¹⁶ atoms/cm³, or 5.50×10¹⁶ atoms/cm³, the efficiency of the process may be increased compared to when the epitaxial layer 2 has different concentrations.

Table 2 is a result of measuring the critical thickness of the epitaxial layer of Comparative Example 1, Comparative Example 2, Embodiment 1, Embodiment 2, Embodiment 3, and Embodiment 4.

TABLE 2

| | | | Critical |
|---|---|---|---|
| | Concentration of | Concentration of | Thickness of |
| | Substrate Layer | Epitaxial Layer | Epitaxial |
| | (atoms/cm³) | (atoms/cm³) | Layer (μm) |
| Comparative | 8.49 × 10¹⁸ | 1.00 × 10¹⁶ | 5.84 |
| Example 1 | | | |
| Comparative | | 4.00 × 10¹⁶ | 5.86 |
| Example 2 | | | |
| Embodiment 1 | 4.89 × 10¹⁸ | 1.00 × 10¹⁶ | 10.72 |
| Embodiment 2 | | 4.00 × 10¹⁶ | 10.79 |
| Embodiment 3 | 3.77 × 10¹⁸ | 1.00 × 10¹⁶ | 14.57 |
| Embodiment 4 | | 4.00 × 10¹⁶ | 14.70 |

### Comparative Example 1

Comparative Example 1 illustrates the critical thickness of the epitaxial layer when the concentration of the substrate layer is 8.49×10¹⁸ atoms/cm³ and the concentration of the epitaxial layer is 1.00×10¹⁶ atoms/cm³. When the concentration of the substrate layer is 8.49×10¹⁸ atoms/cm³ and the concentration of the epitaxial layer is 1.00×10¹⁶ atoms/cm³, the critical thickness of the epitaxial layer is 5.84 μm.

### Comparative Example 2

Comparative Example 2 illustrates the critical thickness of the epitaxial layer when the concentration of the substrate layer is 8.49×10¹⁸ atoms/cm³ and the concentration of the epitaxial layer is 4.00×10¹⁶ atoms/cm³. When the concentration of the substrate layer is 8.49×10¹⁸ atoms/cm³ and the concentration of the epitaxial layer is 4.00×10¹⁶ atoms/cm³, the critical thickness of the epitaxial layer is 5.86 μm.

### Embodiment 1

Embodiment 1 illustrates the critical thickness of the epitaxial layer when the concentration of the substrate layer is 4.89×10¹⁸ atoms/cm³ and the concentration of the epitaxial layer is 1.00×10¹⁶ atoms/cm³. When the concentration of the substrate layer is 4.89×10¹⁸ atoms/cm³ and the concentration of the epitaxial layer is 1.00×10¹⁶ atoms/cm³, the critical thickness of the epitaxial layer is 10.72 μm.

### Embodiment 2

Embodiment 2 illustrates the critical thickness of the epitaxial layer when the concentration of the substrate layer is 4.89×10¹⁸ atoms/cm³ and the concentration of the epitaxial layer is 4.00×10¹⁶ atoms/cm³. When the concentration of the substrate layer is 4.89×10¹⁸ atoms/cm³ and the concentration of the epitaxial layer is 4.00×10¹⁶ atoms/cm³, the critical thickness of the epitaxial layer is 10.79 μm.

### Embodiment 3

Embodiment 3 illustrates the critical thickness of the epitaxial layer when the concentration of the substrate layer is 3.77×10¹⁸ atoms/cm³ and the concentration of the epitaxial layer is 1.00×10¹⁶ atoms/cm³. When the concentration of the substrate layer is 3.77×10¹⁸ atoms/cm³ and the concentration of the epitaxial layer is 1.00×10¹⁶ atoms/cm³, the critical thickness of the epitaxial layer is 14.57 μm.

### Embodiment 4

Embodiment 4 illustrates the critical thickness of the epitaxial layer when the concentration of the substrate layer is 3.77×10¹⁸ atoms/cm³ and the concentration of the epitaxial layer is 4.00×10¹⁶ atoms/cm³. When the concentration of the substrate layer is 3.77×10¹⁸ atoms/cm³ and the concentration of the epitaxial layer is 4.00×10¹⁶ atoms/cm³, the critical thickness of the epitaxial layer is 14.70 μm.

Referring to Table 2, in Embodiments 1 to 4, the critical thickness of the epitaxial layer is 10 μm or more. On the other hand, in Comparative Example 1 and Comparative Example 2, the critical thickness of the epitaxial layer is less than 10 μm. That is, when the concentration of boron (B) included in the substrate layer 1 is about 5.00×10¹⁸ atoms/cm³ or less, the critical thickness of the epitaxial layer may be 10 μm or more. Accordingly, the depth of the photoelectric conversion layer may also be ensured to be 10 μm or more.

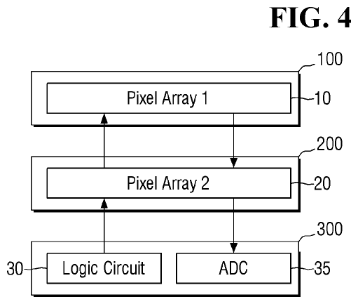

FIG. 4 is an exemplary block diagram of an image sensor according to some embodiments. Referring to FIG. 4, an image sensor according to some embodiments may include a first semiconductor chip 100, a second semiconductor chip 200, and a third semiconductor chip 300. The first semiconductor chip 100, the second semiconductor chip 200, and the third semiconductor chip 300 may be disposed to overlap each other when viewed from a plan perspective (e.g., top-down). The first semiconductor chip 100, the second semiconductor chip 200, and the third semiconductor chip 300 may be sequentially stacked in a vertical direction. The first semiconductor chip 100 may be referred to as an upper plate, the second semiconductor chip 200 may be referred to as a middle plate, and the third semiconductor chip 300 may be referred to as a lower plate.

The first semiconductor chip 100 may include a first pixel array 10. The second semiconductor chip 200 may include a second pixel array 20. The third semiconductor chip 300 may include a logic circuit 30 and an analog digital converter (ADC) 35. The first pixel array 10 may generate electric charges in proportion to the amount of light reaching the first pixel array 10. The second pixel array 20 may convert an optical signal into an electrical signal, that is, an analog signal under the control of the logic circuit 30. The second pixel array 20 may output the analog signal to the ADC 35. The ADC 35 may convert the analog signal into a digital signal. The ADC 35 may provide data based on the digital signal.

Although not shown, the image sensor according to some embodiments may further include a memory cell array. The memory cell array may store therein data based on the digital signal. The data may be image data generated on a frame basis, and the number of the bits of the data may be determined based on the resolution of the ADC 35. The number of the bits of the data may be determined based on the high dynamic range (HDR) supported by the image sensor. In addition, the bits of the data may further include at least one extension bit indicating a data generation position, data information, and the like.

Unlike in the drawings, the first semiconductor chip 100 and the second semiconductor chip 200 may be formed on one chip. A semiconductor chip including a pixel array and a semiconductor chip including a logic circuit may be stacked on top of each other. The image sensor according to some embodiments of the present disclosure will be described as a 3-stack image sensor including the first pixel array 10 and the second pixel array 20 that are formed on different chips and stacked on top of each other.

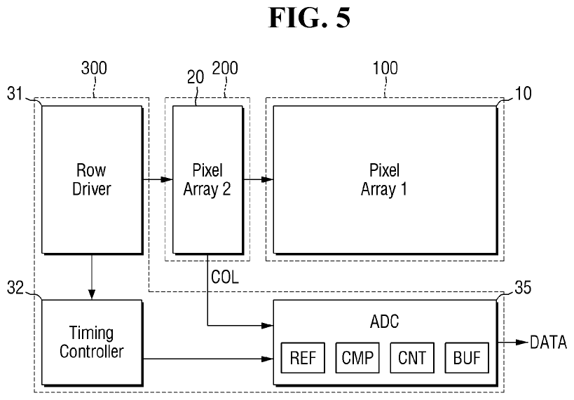

FIG. 5 is a block diagram illustrating the first pixel array, the second pixel array, the logic circuit, and the ADC of FIG. 4. Referring to FIG. 5, the first pixel array 10 is implemented in the first semiconductor chip 100. The second pixel array 20 is implemented in the second semiconductor chip 200. The logic circuit (30 in FIG. 4) is implemented in the third semiconductor chip 300.

The first pixel array 10 may convert incident light and generate electrical signals. The second pixel array 20 may include unit pixels arranged in a matrix form along a row direction and a column direction. The second pixel array 20 may be driven under the control of the logic circuit. Specifically, the logic circuit may control a plurality of transistors included in the second pixel array 20. The plurality of transistors included in the second pixel array 20 may control the electrical signal transmitted from the first pixel array 10.

The logic circuit 30 may efficiently receive data from the second pixel array 20 and generate an image frame. For example, the logic circuit 30 may use a global shutter method in which all unit pixels are simultaneously sensed, a flutter shutter method in which an exposure time during which all unit pixels are sensed simultaneously is adjusted, a coded rolling shutter method or a rolling shutter method in which unit pixels are controlled on a row basis, or the like. The logic circuit 30 may include a row driver 31, a timing controller, and the ADC 35.

The row driver 31 may control the second pixel array 20 on a row basis under the control of the control of the timing controller 32. The row driver 31 may select at least one row from the rows of the second pixel array 20 according to a row address. The row driver 31 may decode the row address and be connected to a select transistor SEL, a reset transistor RG, and a source follower transistor SF included in the second pixel array 20. The second pixel array 20 may be driven by a plurality of driving signals such as a pixel selection signal, a reset signal, and a charge transfer signal received from the row driver 31.

The ADC 35 may be connected to the second pixel array 20 through column lines COL. The ADC 35 may convert analog signals received from the second pixel array 20 through the column lines COL into digital signals. The number of the ADC 35 may be determined based on the number of the unit pixels arranged along one row and the number of the column lines COL. The ADC 35 may be at least one.

For example, the ADC 35 may include a reference signal generator REF, a comparator CMP, a counter CNT, and a buffer BUF. The reference signal generator REF may generate a ramp signal having a specific gradient and provide the ramp signal as a reference signal of the comparator. The comparator CMP may compare the analog signal with the ramp signal of the reference signal generator REF, and may output comparison signals having respective transition points according to valid signal components. The counter CNT may generate a counting signal by performing a counting operation, and may provide the counting signal to the buffer BUF. The buffer BUF may include latch circuits respectively connected to the column lines COL, and may latch the counting signal outputted from the counter CNT in response to the transition of the comparison signal for each column, and output the latched counting signal as data.

In some embodiments, the logic circuit 30 may further include correlated double sampling (CDS) circuits that perform correlated double sampling by calculating a difference between a reference voltage indicating a reset state of the unit pixels and an output voltage indicating a signal component corresponding to the incident light, and output an analog sampling signal corresponding to a valid signal component. The correlated double sampling circuits may be connected to the column lines COL.

The timing controller 32 may control operation timings of the row driver 31 and the ADC 35. The timing controller 32 may provide a timing signal and a control signal to the row driver 31 and the ADC 35. More specifically, the timing controller 32 may control the ADC 35, and the ADC 35 may provide the data to the logic circuit 30 under the control of the timing controller 32. Further, the timing controller 32 may further include circuits that provide a request, a command, or an address to the logic circuit 30 so that the data of the ADC 35 is stored in a memory cell array.

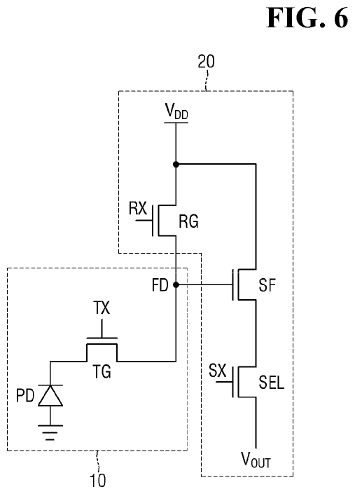

FIG. 6 is a circuit diagram for describing a unit pixel of the first pixel array and the second pixel array of FIG. 4. For reference, FIG. 6 may illustrate a 4T structure of the unit pixel constituting the first pixel array and the second pixel array. Referring to FIG. 6, the first pixel array 10 includes a photoelectric conversion layer PD, a transfer transistor TG, and a floating diffusion region FD. The second pixel array 20 includes the reset transistor RG, the source follower transistor SF, and the select transistor SEL.

The photoelectric conversion layer PD may generate electric charges in proportion to the amount of light incident from the outside. The photoelectric conversion layer PD may be coupled with the transfer transistor TG that transfers the generated and accumulated charges to the floating diffusion region FD. The floating diffusion region FD converts the charges into a voltage, and has a parasitic capacitance so that the charges can be stored cumulatively.

One end of the transfer transistor TG may be connected to the photoelectric conversion layer PD, and the other end of the transfer transistor TG may be connected to the floating diffusion region FD. The transfer transistor TG may be formed of a transistor driven by a predetermined bias (e.g., a transfer signal TX). That is, the transfer transistor TG may transfer the charges generated from the photoelectric conversion layer PD to the floating diffusion region FD in response to the transfer signal TX.

The source follower transistor SF may amplify a change in the electrical potential of the floating diffusion region FD that has received the charges from the photoelectric conversion layer PD and output it to an output line VOUT. When the source follower transistor SF is turned on, a predetermined electrical potential (e.g., a power voltage VDD) provided to the drain of the source follower transistor SF may be transferred to the drain region of the select transistor SEL.

The select transistor SEL may select a unit pixel to be read on a row basis. The select transistor SEL may be formed of a transistor driven by a select line through which a predetermined bias (e.g., a row selection signal SX) is applied. The reset transistor RG may periodically reset the floating diffusion region FD. The reset transistor RG may be formed of a transistor driven by a reset line through which a predetermined bias (e.g., a reset signal RX) is applied. When the reset transistor RG is turned on by the reset signal RX, a predetermined electrical potential (e.g., the power voltage VDD) provided to the drain of the reset transistor RG may be transmitted to the floating diffusion region FD.

As shown in the drawing, as the area of the unit pixel decreases, the photoelectric conversion layer PD and the transfer transistor TG may be formed on the first semiconductor chip (100 of FIG. 4), and the reset transistor RG, the source follower transistor (SF) and the select transistor SEL may be formed on the second semiconductor chip (200 of FIG. 4). The first semiconductor chip and the second semiconductor chip may be aligned to form a unit pixel.

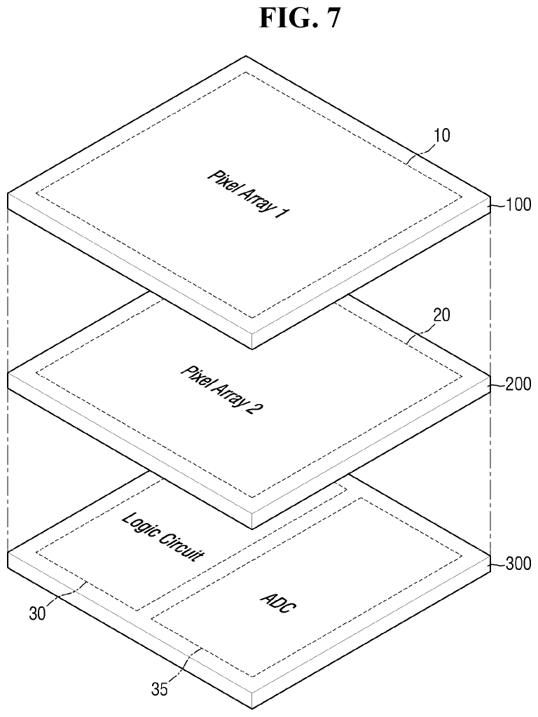

FIG. 7 is a perspective view for three-dimensionally demonstrating the first pixel array, the second pixel array, the logic circuit, and the ADC of the image sensor of FIG. 4. Referring to FIG. 7, in the image sensor according to some embodiments, the first to third semiconductor chips 100, 200, and 300 may be sequentially stacked. In FIG. 4, the sizes of the first semiconductor chip 100, the second semiconductor chip 200, and the third semiconductor chip 300 are illustrated as being same, but this is only for the convenience of description, and the present disclosure is not limited thereto. The sizes of the first semiconductor chip 100, the second semiconductor chip 200, and the third semiconductor chip 300 may be different from each other. As described above, the first pixel array 10 is disposed on the first semiconductor chip 100, and the second pixel array 20 is disposed on the second semiconductor chip 200. The logic circuit 30 and the ADC 35 are disposed on the third semiconductor chip 300.

In the first semiconductor chip 100, a plurality of unit pixels may be arranged in a two-dimensional array structure on a two-dimensional plane. Although not shown, the first pixel array 10 may include a sensor array region and a pad region. The sensor array region may be disposed, for example, in the central portion of the first semiconductor chip 100, and the pad region may be disposed, for example, at the periphery of the first semiconductor chip 100, but the present disclosure is not limited thereto.

In the sensor array region, active pixels that receive light and generate an active signal may be arranged. The second pixel array 20 may transmit a control signal to the sensor array region of the first pixel array 10, and may transmit an output signal of the unit pixel to the logic circuit 30 of the third semiconductor chip 300. The pad region may be configured to transmit and receive electrical signals between an unknown sensor and an external device according to some embodiments. The logic circuit 30 may include circuits for processing pixel signals received from the unit pixels. The logic circuit 30 may receive an image signal from the ADC 35 and process the received image signal.

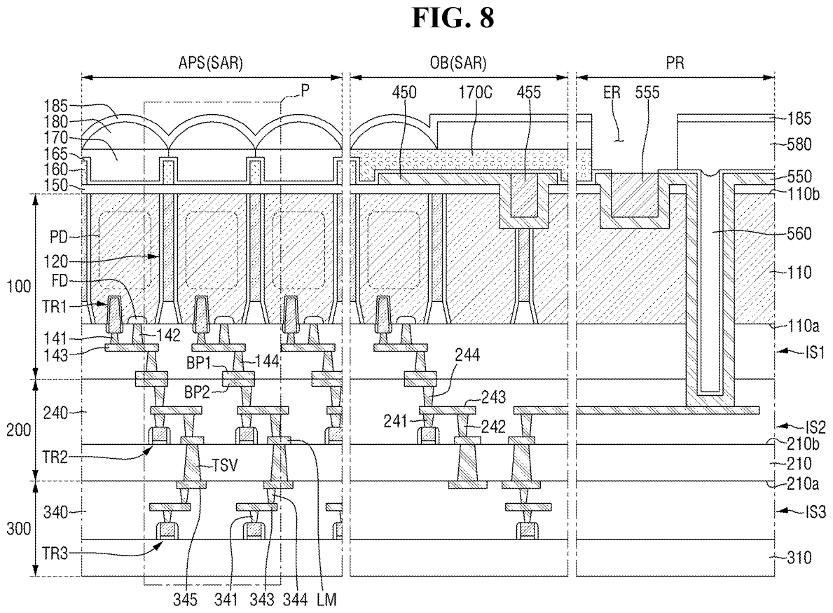

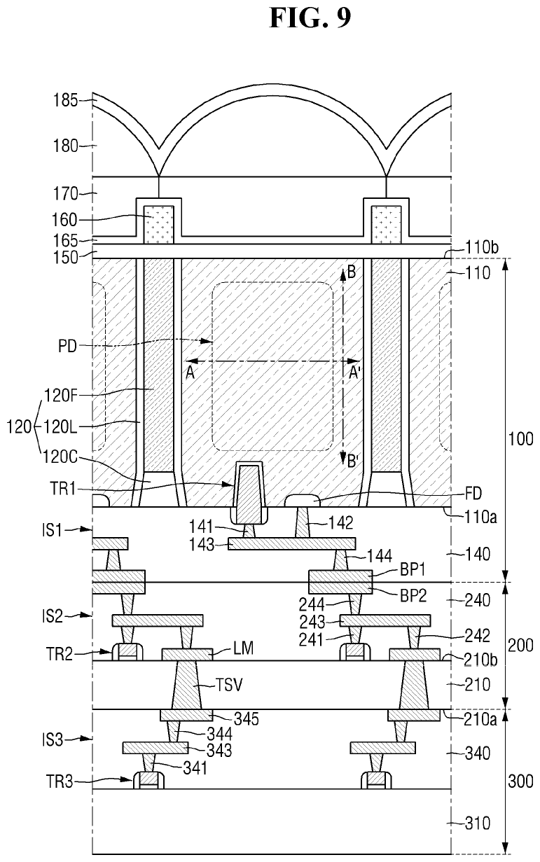

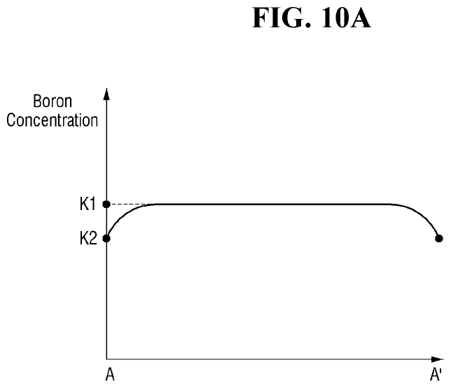

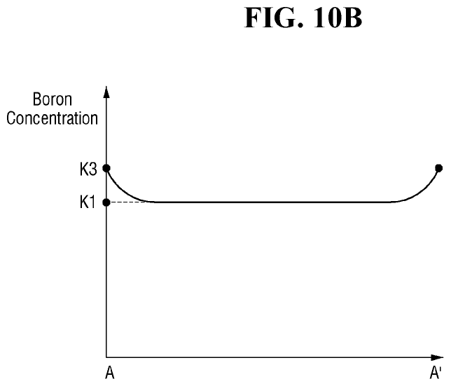

FIG. 8 is an exemplary cross-sectional view of the image sensor of FIG. 7. FIG. 9 is an enlarged view of area P of FIG. 8. FIGS. 10A and 10B are graphs illustrating the concentration of boron (B) included in the first substrate in a cross section taken along line A-A′ of FIG. 9. Referring to FIGS. 8 and 9, the first semiconductor chip 100 and the second semiconductor chip 200 of the image sensor according to some embodiments may include a sensor array region SAR and a pad region PR.

The sensor array region SAR may include areas corresponding to the first pixel array 10 and the second pixel array 20 of FIGS. 4 to 6. For example, a plurality of unit pixels arranged two-dimensionally (e.g., in a matrix form) may be formed in the sensor array region SAR. The sensor array region SAR may include a light receiving region APS and a light blocking region OB. Active pixels that receive light to generate active signals may be arranged in the light receiving region APS. Optical black pixels that generate optical black signals by blocking light may be arranged in the light blocking region OB. The light blocking region OB may be formed, for example, along the periphery of the light receiving region APS, but this is merely exemplary. In some embodiments, although not shown, dummy pixels may be formed in the light receiving region APS adjacent to the light blocking region OB. The dummy pixels may be pixels that do not generate an active signal.

The pad region PR may be formed around the sensor array region SAR. The pad region PR may be formed adjacent to the edge of the image sensor according to some embodiments, but this is merely exemplary. The pad region PR may be connected to an external device or the like to allow the image sensor according to some embodiments to transmit and receive electrical signals to and from the external device.

The image sensor according to some embodiments may include a first substrate 110, a pixel isolation pattern 120, a first wiring structure IS1, a surface insulating layer 150, a first color filter 170, a grid pattern 160, a microlens 180, a second wiring structure IS2, a second substrate 210, a third wiring structure IS3, a third substrate 310, a through via TSV, and a second pad 555.

The substrate 110 may have an epitaxial layer formed on a base substrate. For example, the first substrate 110 may be the epitaxial layer 2 of FIG. 1. However, the technical spirit of the present disclosure is not limited thereto, and the first substrate 110 may also be a silicon substrate, or may also contain other materials, such as: silicon germanium (SiGe), indium antimonide, lead tellurium compound, indium arsenide, indium phosphide, gallium arsenide (GaAs), or gallium antimonide.

The first substrate 110 may be doped with boron (B). The concentration of boron (B) included in the first substrate 110 may be, for example, 1×10¹⁶ atoms/cm³ or more and 6×10¹⁶ atoms/cm³ or less. Preferably, the concentration of boron (B) contained in the first substrate 110 may be 4×10¹⁶ atoms/cm³ or more and 5.5×10¹⁶ atoms/cm³ or less. More preferably, the concentration of boron (B) included in the first substrate 110 may be 5×10¹⁶ atoms/cm³. However, the technical spirit of the present disclosure is not limited thereto.

Referring to FIGS. 10A and 10B, the concentration of boron (B) in the center portion of the first substrate 110 and the edge portion of the first substrate 110 may be different. The edge portion of the first substrate 110 may be a portion close to a first surface 110a and a second surface 110b of the first substrate 110. The center portion of the first substrate 110 may be an area between the edge portions of the first substrate 110.

For example, in FIG. 10A, the concentration of boron (B) included in the first substrate 110 in the center portion of the first substrate 110a may be a first concentration K1. The first concentration K1 may be constant. The concentration of boron (B) included in the first substrate 110 at the edge portion of the first substrate 110 may be a second concentration K2. The first concentration K1 may be greater than the second concentration K2. For example, the first concentration K1 may be about 5% greater than the second concentration K2.

The concentration of boron (B) included in the first substrate 110 in the center portion of the first substrate 110 may be constant, but the concentration of boron (B) may gradually decrease as going from a specific position toward the edge portion of the first substrate 110. However, the technical spirit of the present disclosure is not limited thereto.

In FIG. 10B, the concentration of boron (B) included in the first substrate 110 in the center portion of the first substrate 110 may be the first concentration K1. The first concentration K1 may be constant. The concentration of boron (B) included in the first substrate 110 at the edge portion of the first substrate 110 may be a third concentration K3. The first concentration K1 may be less than the third concentration K3. For example, the first concentration K1 may be about 5% less than the third concentration K3.

The concentration of boron (B) included in the first substrate 110 in the center portion of the first substrate 110 may be constant, but the concentration of boron (B) may gradually increase as going from a specific position toward the edge portion of the first substrate 110. However, the technical spirit of the present disclosure is not limited thereto.

As such, the concentration of boron (B) in the center portion of the first substrate 110 and the concentration of boron (B) in the edge portion of the first substrate 110 may have a difference of about 5%. However, the technical spirit of the present disclosure is not limited thereto.

Referring back to FIGS. 8 and 9, the first substrate 110 may include the first surface 110a and the second surface 110b that are opposite to each other. In some embodiments, the second surface 110b of the first substrate 110 may be a light receiving surface on which light is incident. That is, the image sensor according to some embodiments may be a backside illuminated (BSI) image sensor.

A plurality of unit pixels may be formed on the first substrate 110 of the sensor array region SAR. Although not shown, a plurality of pixels arranged two-dimensionally (e.g., in a matrix form) may be formed in the light receiving region APS.

Each unit pixel may include the photoelectric conversion layer PD, the floating diffusion region FD, and the first transistor TR1. The photoelectric conversion layer PD may be formed in the first substrate 110 of the light receiving region APS and the light blocking area OB. The photoelectric conversion layer PD may generate electric charges in proportion to the amount of light incident from the outside. The photoelectric conversion layer PD may transfer the generated and accumulated charges to the floating diffusion region FD.

The floating diffusion region FD may be formed in the first substrate 110 of the light receiving region APS and the light blocking region OB. The floating diffusion region FD may be an area that converts the electric charges into a voltage. Since the floating diffusion region FD has parasitic capacitance, electric charges may be stored cumulatively.

The first transistor TR1 may be buried in the first substrate 110. The first transistor TR1 may be, for example, the transfer transistor TG in FIG. 6. One end of the first transistor TR1 may be connected to the photoelectric conversion layer PD, and the other end of the first transistor TR1 may be connected to the floating diffusion region FD. The first transistor TR1 may transfer the charges generated from the photoelectric conversion layer PD to the floating diffusion region FD.

The pixel isolation pattern 120 may be formed in the first substrate 110 of the sensor array region SAR. The pixel isolation pattern 120 may be formed, for example, by filling an insulating material in deep trenches formed by patterning the first substrate 110. The pixel isolation pattern 120 may penetrate the first substrate 110. For example, the pixel isolation pattern 120 may extend from the first surface 110a to the second surface 110b. The pixel isolation pattern 120 may be a front deep trench isolation (FDTI) pattern.

The pixel isolation pattern 120 may define a plurality of unit pixels. The pixel isolation pattern 120 may be formed in a grid shape in plan view to separate the plurality of unit pixels from each other.

The first wiring structure IS1 may be formed on the first substrate 110. For example, the first wiring structure IS1 may cover the first surface 110a of the first substrate 110. The first substrate 110 and the first wiring structure IS1 may constitute the first semiconductor chip 100. The first wiring structure IS1 may be constituted with a plurality of first wiring patterns 143, a plurality of contacts 141, 142, and 144, and first bonding pads BP1. For example, the first wiring structure IS1 may include a first inter-wiring insulating layer 140, the plurality of first wiring patterns 143 in the first inter-wiring insulating layer 140, the plurality of contacts 141, 142, and 144, and the first bonding pad BP1. In FIG. 8, the number of the layers of the wiring patterns constituting the first wiring structure IS1 and the layout thereof are merely exemplary. The first inter-wiring insulating layer 140 may include, for example, at least one of silicon oxide, silicon nitride, silicon oxynitride, or a low-k material having a lower dielectric constant than silicon oxide, but is not limited thereto.

The first contact 141 may be electrically connected to the first transistor TR1 and the first wiring pattern 143. The second contact 142 may be electrically connected to the floating diffusion region FD and the first wiring pattern 143. The third contact 144 may be electrically connected to the first wiring pattern 143 and the first bonding pad BP1. That is, the floating diffusion region FD, the first wiring pattern 143, and the first bonding pad BP1 may be electrically connected to each other.

Each of the first wiring pattern 143, the first contact 141, the second contact 142, and the third contact 144 may include, for example, at least one of tungsten (W), copper (Cu), aluminum (Al), gold (Au), silver (Ag), or an alloy thereof, but is not limited thereto.

The first bonding pad BP1 may be disposed in the first inter-wiring insulating layer 140. On the first inter-wiring insulating layer 140, one surface of the first bonding pad BP1 may be exposed. The bottom surface of the first bonding pad BP1 may be positioned on the same plane as the bottom surface of the first inter-wiring insulating layer 140. The first bonding pad BP1 may be bonded to a second bonding pad BP2 to be described later. The first inter-wiring insulating layer 140 and the second inter-wiring insulating layer 240 may be bonded to each other using the first bonding pad BP1 and the second bonding pad BP2.

The first bonding pad BP1 may include, for example, copper (Cu), but is not limited thereto.

The second substrate 210 may be a bulk silicon or silicon-on-insulator (SOI) substrate. The second substrate 210 may be a silicon substrate, or may include other materials such as silicon germanium, indium antimonide, lead tellurium compound, indium arsenide, indium phosphide, gallium arsenide, or gallium antimonide. Alternatively, the second substrate 210 may have an epitaxial layer formed on a base substrate.

The second substrate 210 may include a third surface 210a and a fourth surface 210b. The fourth surface 210b of the second substrate 210 may be a surface facing the first semiconductor chip 100. The third surface 210a of the second substrate 210 may be a surface opposite to the fourth surface 210b of the second substrate 210.

Second transistors TR2 may be formed on the third surface 210a of the second substrate 210. The second transistors TR2 may be, for example, the reset transistor RG of FIG. 6, the source follower transistor SF of FIG. 6, and the select transistor SEL of FIG. 6. The second transistors TR2 may be electrically connected to the floating diffusion region FD of the first semiconductor chip 100.

The second wiring structure IS2 may be formed on the second substrate 210. For example, the second wiring structure IS2 may cover the fourth surface 210b of the second substrate 210. The second substrate 210 and the second wiring structure IS2 may constitute the second semiconductor chip 200.

The second wiring structure IS2 may be attached to the first wiring structure IS1. For example, as shown in FIG. 8, the top surface of the second wiring structure IS2 may be attached to the bottom surface of the first wiring structure IS1. Specifically, the bottom surface of the first inter-wiring insulating layer 140 and the top surface of the second inter-wiring insulating layer 240 may be bonded to each other.

The second wiring structure IS2 may include the second inter-wiring insulating layer 240, and a plurality of second wiring patterns 243, a plurality of contacts 241, 242 and 244, the second bonding pad BP2, and a landing metal LM disposed in the second inter-wiring insulating layer 240. In FIG. 8, the number of the layers of the wiring patterns constituting the second wiring structure IS2 and the layout thereof are merely exemplary and are not limited thereto. The second inter-wiring insulating layer 240 may include, for example, at least one of silicon oxide, silicon nitride, silicon oxynitride, or a low-k material having a lower dielectric constant than silicon oxide, but is not limited thereto.

The fourth contact 241 may be electrically connected to the second transistor TR2 and the second wiring pattern 243. The fifth contact 242 may be electrically connected to the landing metal LM and the second wiring pattern 243. The sixth contact 244 may be electrically connected to the second bonding pad BP2 and the second wiring pattern 243. That is, the second transistor TR2 may be electrically connected to the floating diffusion region FD using the plurality of contacts, the plurality of wiring patterns, and the bonding pads.

Each of the fourth contact 241, the fifth contact 242, the sixth contact 244, and the second wiring pattern 243 may include, for example, at least one of tungsten (W), copper (Cu), aluminum (Al), gold (Au), silver (Ag), or an alloy thereof, but is not limited thereto.

The second bonding pad BP2 may be disposed in the second inter-wiring insulating layer 240. In the second inter-wiring insulating layer 240, one surface of the second bonding pad BP2 may be exposed. The top surface of the second bonding pad BP2 may be positioned on the same plane as the top surface of the second inter-wiring insulating layer 240. The second bonding pad BP2 may be bonded to the first bonding pad BP1. The first inter-wiring insulating layer 140 and the second inter-wiring insulating layer 240 may be bonded to each other using the first bonding pad BP1 and the second bonding pad BP2.

Although not shown, a first bonding insulating layer may be disposed on the bottom surface of the first inter-wiring insulating layer 140. A second bonding insulating layer may be disposed on the top surface of the second inter-wiring insulating layer 240. In this case, the first bonding pad BP1 may be disposed in the first bonding insulating layer. The second bonding pad BP2 may be disposed in the second bonding insulating layer. The first bonding insulating layer and the second bonding insulating layer may be attached to each other.

A part of the second wiring pattern 243 may extend from the sensor array region SAR to the pad region PR. A part of the second wiring pattern 243 may be electrically connected to the second pad 555 of the pad region PR. A part of the second wiring pattern 243 may be electrically connected to a third transistor TR3 through the through via TSV, which will be described later.

The second wiring pattern 243 may include, for example, at least one of tungsten (W), copper (Cu), aluminum (Al), gold (Au), silver (Ag), or an alloy thereof, but is not limited thereto.

The landing metal LM may be disposed in the second inter-wiring insulating layer 240. In the second inter-wiring insulating layer 240, one surface of the landing metal LM may be exposed. The bottom surface of the landing metal LM may be positioned on the same plane as the bottom surface of the second inter-wiring insulating layer 240. The landing metal LM may be electrically connected to the through vias TSV. The landing metal LM may include a conductive material. For example, the landing metal LM may include a metal material such as copper or lead.

Through vias TSV penetrating the second substrate 210 may be further included in the second substrate 210. The through vias TSV may penetrate the second substrate 210 to be electrically connected to the landing metal LM and a pad metal 345 to be described later. Some of the through vias TSV may electrically connect the second transistor TR2 to the first transistor TR1. Some others of the through vias TSV may connect the second transistor TR2 to the second pad 555. Each of the through vias TSV may include a conductive material.

The third substrate 310 may be a bulk silicon or silicon-on-insulator (SOI) substrate. The third substrate 310 may be a silicon substrate, or may include other materials such as silicon germanium, indium antimonide, lead tellurium compound, indium arsenide, indium phosphide, gallium arsenide, or gallium antimonide. Alternatively, the third substrate 310 may have an epitaxial layer formed on a base substrate.

The third substrate 310 may include a top surface and a bottom surface. The top surface of the third substrate 310 may be a surface facing the second semiconductor chip 200. The bottom surface of the third substrate 310 may be a surface opposite to the top surface of the third substrate 310.

The third transistors TR3 may be formed on the top surface of the third substrate 310. The third transistors TR3 may be, for example, the logic circuit of FIG. 4. The third transistors TR3 may be electrically connected to the second transistors TR2 of the second semiconductor chip 200.

The third wiring structure IS3 may be formed on the third substrate 310. For example, the third wiring structure IS3 may cover the top surface of the third substrate 310. The third substrate 310 and the third wiring structure IS3 may constitute the third semiconductor chip 300.

The third wiring structure IS3 may be attached to the second substrate 210. For example, as illustrated in FIG. 5, the third surface 210a of the second substrate 210 may be attached to the top surface of the third wiring structure IS3.

The third wiring structure IS3 may include a third inter-wiring insulating layer 340, and third wiring patterns 343, a plurality of contacts 341 and 344, and a pad metal 345 disposed in the third inter-wiring insulating layer 340. In FIG. 8, the number of layers of the wiring patterns constituting the third wiring structure IS3 and the layout thereof are merely exemplary and are not limited thereto. The third inter-wiring insulating layer 340 may include, for example, at least one of silicon oxide, silicon nitride, silicon oxynitride, or a low-k material having a lower dielectric constant than silicon oxide, but is not limited thereto.

The seventh contact 341 may be electrically connected to the third transistor TR3 and the third wiring pattern 343. The eighth contact 344 may be electrically connected to the pad metal 345 and the third wiring pattern 343. Each of the seventh contact 341, the eighth contact 344, and the third wiring pattern 343 may include, for example, tungsten (W), copper (Cu), aluminum (Al), gold (Au), and silver (Ag), and at least one of alloys thereof, but is not limited thereto.

The pad metal 345 may be disposed in the third inter-wiring insulating layer 340. The third inter-wiring insulating layer 340 may expose one surface of the pad metal 345. The exposed pad metal 345 may be in contact with the through vias TSV. The pad metal 345 may include a conductive material. The pad metal 345 may include, for example, copper, but is not limited thereto.

The surface insulating layer 150 may be formed on the second surface 110b of the first substrate 110. The surface insulating layer 150 may extend along the second surface 110b of the first substrate 110. In some embodiments, at least a part of the surface insulating layer 150 may be in contact with the pixel isolation pattern 120.

The surface insulating layer 150 may include an insulating material. For example, the surface insulating layer 150 may include at least one of silicon oxide, silicon nitride, silicon oxynitride, aluminum oxide, hafnium oxide, or a combination thereof, but is not limited thereto.

The surface insulating layer 150 may function as an anti-reflection film to prevent reflection of light incident on the first substrate 110, thereby improving a light receiving rate of the photoelectric conversion layer PD. In addition, the surface insulating layer 150 functions as a planarization layer, so that the first color filter 170 and the microlens 180, which will be described later, may be formed at a uniform height.

The first color filter 170 may be formed on the surface insulating layer 150 of the light receiving region APS. In some embodiments, the first color filter 170 may be arranged to correspond to each unit pixel. For example, a plurality of first color filters 170 may be arranged two-dimensionally (e.g., in a matrix form).

The first color filters 170 may have various color filters according to the unit pixels. For example, the first color filters 170 may be arranged in a Bayer pattern including a red filter, a green filter, and a blue filter. However, this is merely exemplary, and the first color filters 170 may include a yellow filter, a magenta filter, and a cyan filter, and may further include a white filter.

The grid pattern 160 may be formed on the surface insulating layer 150. The grid pattern 160 may be formed in a grid shape in plan view and interposed between the plurality of the first color filters 170.

The grid pattern 160 may include a low refractive index material having a lower refractive index than silicon (Si). For example, the grid pattern 160 may include at least one of silicon oxide, aluminum oxide, tantalum oxide, or a combination thereof, but is not limited thereto. The grid pattern 160 including the low refractive index material may improve the quality of the image sensor by refracting or reflecting the light obliquely incident to the image sensor.

In some embodiments, the first passivation layer 165 may be formed on the surface insulating layer 150 and the grid pattern 160. The first passivation layer 165 may be interposed between the surface insulating layer 150 and the first color filter 170 and between the grid pattern 160 and the first color filter 170. For example, the first passivation layer 165 may extend along the profiles of the top surface of the surface insulating layer 150, and the side and top surfaces of the grid pattern 160.

The first passivation layer 165 may include, for example, aluminum oxide, but is not limited thereto. The first passivation layer 165 may prevent damage to the surface insulating layer 150 and the grid pattern 160.

The microlens 180 may be formed on the first color filter 170. The microlens 180 may be arranged to correspond to each unit pixel. For example, a plurality of microlenses 180 may be arranged two-dimensionally (e.g., in a matrix form) in plan view.

The microlens 180 may have a convex shape and may have a predetermined radius of curvature. Accordingly, the microlens 180 may condense light incident on the photoelectric conversion layer PD. The microlens 180 may include, for example, a light transmitting resin, but is not limited thereto.

In some embodiments, a second passivation layer 185 may be formed on the microlens 180. The second passivation layer 185 may extend along the surface of the microlens 180. The second passivation layer 185 may include, for example, an inorganic oxide layer. For example, the second passivation layer 185 may include at least one of silicon oxide, titanium oxide, zirconium oxide, hafnium oxide, or a combination thereof, but is not limited thereto. In some embodiments, the second passivation layer 185 may include low temperature oxide (LTO).

The second passivation layer 185 may protect the microlens 180 from the outside. For example, the second passivation layer 185 may include the inorganic oxide layer, thereby protecting the microlenses 180 including an organic material. In addition, the second passivation layer 185 may improve the light condensing ability of the microlens 180. For example, the second passivation layer 185 may fill a space between the microlenses 180, thereby reducing reflection, refraction, scattering, and the like of incident light reaching the space between the microlenses 180.

The image sensor according to some embodiments may further include a first connection structure 450 and a second connection structure 550.

The first connection structure 450 may be formed in the light blocking region OB. The first connection structure 450 may be formed on the surface insulating layer 150 of the light blocking region OB. The first connection structure 450 may be in contact with the pixel isolation pattern 120. For example, a first trench exposing the pixel isolation pattern 120 may be formed in the first substrate 110 and the surface insulating layer 150 in the light blocking region OB. The first connection structure 450 may be formed in the first trench to be in contact with the pixel isolation pattern 120 in the light blocking region OB. The first connection structure 450 may extend along the profiles of the side surface and the bottom surface of the first trench.

The first connection structure 450 may be electrically connected to the pixel isolation pattern 120 to apply a ground voltage or a negative voltage to the pixel isolation pattern 120. Accordingly, charges generated by ESD or the like may be discharged to the first connection structure 350 through the pixel isolation pattern 120, and an electrostatic discharge (ESD) bruise defect may be effectively prevented.

The first connection structure 450 may include, for example, a titanium (Ti) film, a titanium nitride (TiN) film, and a tungsten (W) film that are sequentially stacked.

In some embodiments, a first pad 455 filling the first trench may be formed on the first connection structure 450. The first pad 455 may include, for example, at least one of tungsten (W), copper (Cu), aluminum (Al), gold (Au), silver (Ag), or an alloy thereof, but is not limited thereto.

In some embodiments, the first passivation layer 165 may cover the first connection structure 450 and the first pad 455. For example, the first passivation layer 165 may extend along the profiles of the first connection structure 450 and the first pad 455.

In some embodiments, a second color filter 170C may be formed on the first connection structure 450. For example, the second color filter 170C may be formed to cover a part of the first passivation layer 165 in the light blocking region OB. The second color filter 170C may include, for example, a blue filter, but is not limited thereto.

The second connection structure 550 may be formed in the pad region PR. The second connection structure 550 may be formed on the surface insulating layer 150 of the pad region PR. The second connection structure 550 may electrically connect the third semiconductor chip 300 to an external device or the like.

For example, a second trench exposing the second wiring pattern 243 may be formed in the first semiconductor chip 100 and the second semiconductor chip 200 of the pad region PR. The second connection structure 550 may be formed in the second trench to be in contact with the second wiring pattern 243. Also, a third trench may be formed in the first substrate 110 of the pad region PR. The second connection structure 550 may be formed and exposed in the third trench. In some embodiments, the second connection structure 550 may extend along the profiles of the side surfaces and the bottom surfaces of the second and third trenches.

In some embodiments, a filling insulating layer 560 filling the second trench may be formed on the second connection structure 550. The filling insulating layer 560 may include, for example, at least one of silicon oxide, aluminum oxide, tantalum oxide, or a combination thereof, but is not limited thereto.

In some embodiments, a second pad 555 filling the third trench may be formed on the second connection structure 550. The second pad 555 may include, for example, at least one of tungsten (W), copper (Cu), aluminum (Al), gold (Au), silver (Ag), or an alloy thereof, but is not limited thereto. The second connection structure 550 may include a titanium (Ti) film, a titanium nitride (TiN) film, and a tungsten (W) film sequentially stacked in the second trench.

In some embodiments, the second passivation layer 185 and the third passivation layer 580 may expose the second pad 555. For example, an exposure opening ER exposing the second pad 555 may be formed in the second passivation layer 185 and the third passivation layer 580. Accordingly, the second pad 555 may be electrically connected to the external device or the like to allow the image sensor according to some embodiments to transmit and receive electrical signals to and from the external device.

In FIG. 9, the pixel isolation pattern 120 may penetrate the first substrate 110 in a vertical direction. One surface of the pixel isolation pattern 120 may be positioned on the same level as the second surface 110b of the first substrate 110. The other surface of the pixel isolation pattern 120 may be positioned at the same level as the first surface 110a of the first substrate 110.

The pixel isolation pattern 120 may include a pixel isolation liner layer 120L, a pixel isolation filling layer 120F, and the pixel isolation capping layer 120C. The pixel isolation liner layer 120L may be disposed on the sidewall of the pixel isolation filling layer 120F and the sidewall of the pixel isolation capping layer 120C. The pixel isolation filling layer 120F may be disposed between the pixel isolation liner layers 120L. The pixel isolation capping layer 120C may be disposed on the pixel isolation filling layer 120F.

The pixel isolation liner layer 120L may include an oxide layer having a lower refractive index than that of the first substrate 110. For example, the pixel isolation liner layer 120L may include at least one of silicon oxide, aluminum oxide, tantalum oxide, or a combination thereof, but is not limited thereto. The pixel isolation liner layer 120L having the lower refractive index than the first substrate 110 may refract or reflect the light that is obliquely incident to the photoelectric conversion layer PD. In addition, the pixel isolation liner layer 120L may prevent photocharges generated in a specific unit pixel by the incident light from moving to an adjacent unit pixel due to random drift. That is, the pixel isolation liner layer 120L may improve the light receiving rate of the photoelectric conversion layer PD, thereby improving the quality of the image sensor according to some embodiments.

In some embodiments, the pixel isolation filling layer 120F may include a conductive material. For example, the pixel isolation filling layer 120F may include polysilicon (poly Si), but is not limited thereto. In some embodiments, a ground voltage or a negative voltage may be applied to the pixel isolation filling layer 120F including the conductive material. Accordingly, an electrostatic discharge (ESD) bruise defect of the image sensor according to some embodiments may be effectively prevented. Here, the ESD bruise defect refers to a phenomenon that electric charges generated by ESD or the like are accumulated on the surface (for example, the second surface 110b) of the substrate, thereby causing a stain such as bruise in the image generated.

In some embodiments, the pixel isolation capping layer 120C may include an insulating material. For example, the pixel isolation capping layer 120C may include an oxide-based insulating material, but is not limited thereto.

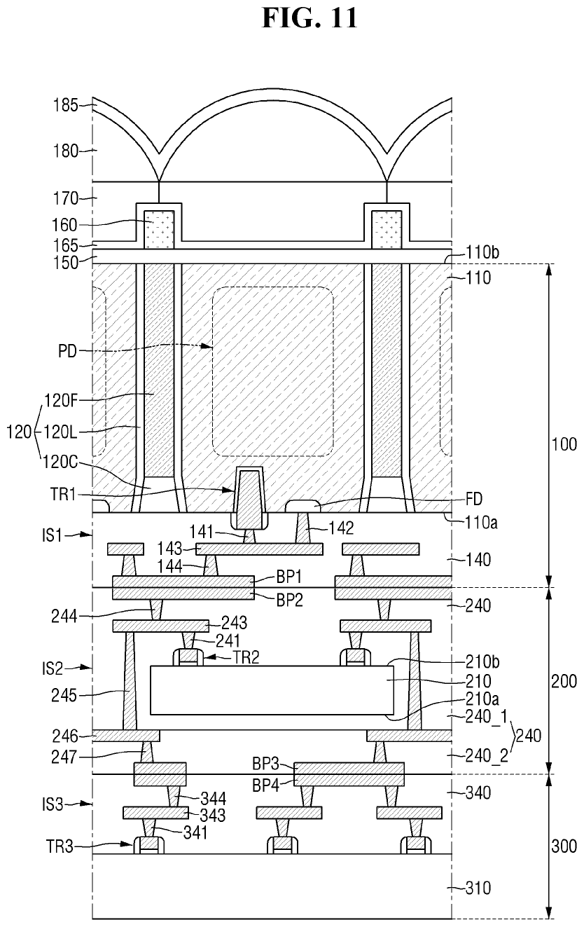

FIG. 11 is a cross-sectional view of an image sensor according to some embodiments. For reference, FIG. 11 may be an enlarged view of the light receiving region APS of an image sensor according to some embodiments.

Referring to FIG. 11, in the image sensor according to some embodiments, the second inter-wiring insulating layer 240 and the third inter-wiring insulating layer 340 may be bonded to each other. In some embodiments, the second wiring structure IS2 may include a fourth wiring pattern 246, a ninth contact 245, a tenth contact 247, and a third bonding pad BP3. The third wiring structure IS3 may include a fourth bonding pad BP4. In FIG. 11, the layer number and disposition of wiring patterns constituting the second wiring structure IS2 and the third wiring structure IS3 are merely exemplary.

In some embodiments, the second inter-wiring insulating layer 240 may include a first sub-insulating layer 240_1 and a second sub-insulating layer 240_2. The first sub-insulating layer 240_1 may surround the second substrate 210. The second sub-insulating layer 240_2 may be disposed on the first sub-insulating layer 240_1. The second sub-insulating layer 240_2 may be bonded to the third inter-wiring insulating layer 340.

The ninth contact 245 may connect the fourth wiring pattern 246 to the second wiring pattern 243. A part of the ninth contact 245 may overlap the second substrate 210 in a horizontal direction. The ninth contact 245 may pass through a part of the first sub-insulating layer 240_1 to be electrically connected to the second wiring pattern 243.

The fourth wiring pattern 246 may be formed on the first sub-insulating layer 240_1. The fourth wiring pattern 246 may be buried in the second sub-insulating layer 240_2. The top surface of the fourth wiring pattern 246 may be one surface of the first sub-insulating layer 240_1 or one surface of the second sub-insulating layer 240_2.

The tenth contact 247 may connect the fourth wiring pattern 246 to the third bonding pad BP3. The tenth contact 247 may be formed in the second sub-insulating layer 240_2.

The ninth contact 245, the fourth wiring pattern 246, and the tenth contact 247 may include, for example, tungsten (W), copper (Cu), aluminum (Al), gold (Au), or silver (Ag), and at least one of alloys thereof, but is not limited thereto.

The third bonding pad BP3 may be disposed in the second sub-insulating layer 240_2. One surface of the third bonding pad BP3 may be exposed on the second sub-insulating layer 240_2. A bottom surface of the third bonding pad BP3 may be positioned on the same plane as a bottom surface of the second sub-insulating layer 240_2. The third bonding pad BP3 may be bonded to the fourth bonding pad BP4 to be described later. The second inter-wiring insulating layer 240 and the third inter-wiring insulating layer 340 may be bonded to each other using the third bonding pad BP3 and the fourth bonding pad BP4.

The third bonding pad BP3 may include, for example, copper (Cu), but is not limited thereto.

The fourth bonding pad BP4 may be disposed in the third inter-wiring insulating layer 340. One surface of the fourth bonding pad BP4 may be exposed on the third inter-wiring insulating layer 340. The fourth bonding pad BP4 may be bonded to the third bonding pad BP3. The second inter-wiring insulating layer 240 and the third inter-wiring insulating layer 340 may be bonded to each other using the fourth bonding pad BP4 and the third bonding pad BP3.

The fourth bonding pad BP4 may include, for example, copper (Cu), but is not limited thereto.

In some embodiments, the eighth contact 344 may electrically connect the third wiring pattern 343 and the fourth bonding pad BP4 to each other, but is not limited thereto.

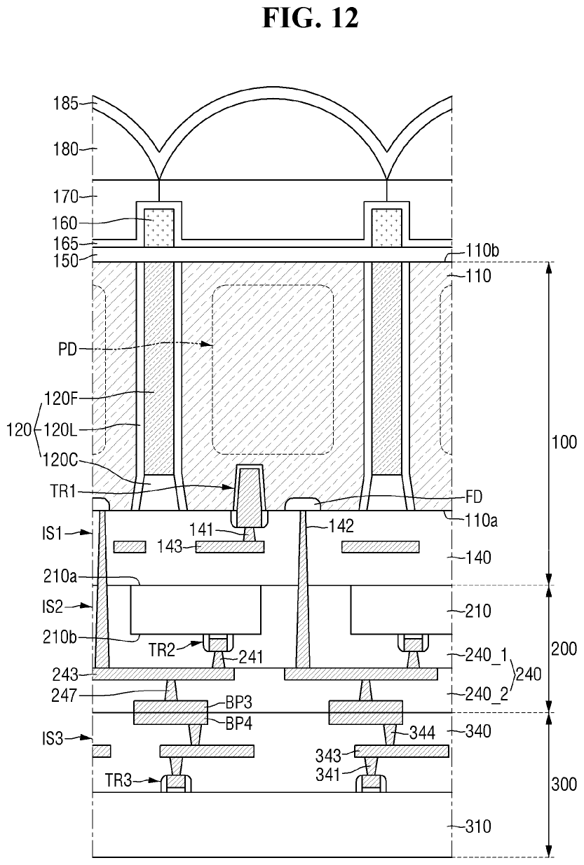

FIG. 12 is a cross-sectional view of an image sensor according to some embodiments. For reference, FIG. 12 may be an enlarged view of the light receiving region APS of an image sensor according to some embodiments. For simplicity of description, the same description as that with reference to FIG. 11 will be omitted.

Referring to FIG. 12, the second contact 142 may penetrate a part of the first inter-wiring insulating layer 140 and the second inter-wiring insulating layer 240. In some embodiments, the second inter-wiring insulating layer 240 may include the first sub-insulating layer 240_1 and the second sub-insulating layer 240_2. The first sub-insulating layer 240_1 may be disposed on the first inter-wiring insulating layer 140. The second sub-insulating layer 240_2 may be disposed on the first sub-insulating layer 240_1.

In some embodiments, the first inter-wiring insulating layer 140 may be in contact with the third surface 210a of the second substrate 210. The third surface 210a of the second substrate 210 may face the first surface 110a of the first substrate 110. The fourth surface 210b of the second substrate 210 may be opposite to the third surface 210a. The fourth surface 210b of the second substrate 210 may be in contact with the second sub-insulating layer 240_2.

The second contact 142 may penetrate the first sub-insulating layer 240_1 and the first inter-wiring insulating layer 140 to be connected to the floating diffusion region FD. The second contact 142 may be connected to the second wiring pattern 243. That is, the floating diffusion region FD and the second transistor TR2 may be electrically connected to each other through the second contact 142 and the second wiring pattern 243.

The second wiring pattern 243 may be disposed in the second sub-insulating layer 240_2. The second wiring pattern 243 may be connected to the tenth contact 247. The tenth contact 247 may be connected to the third bonding pad BP3. The tenth contact 247 and the third bonding pad BP3 may be disposed in the second sub-insulating layer 240_2.

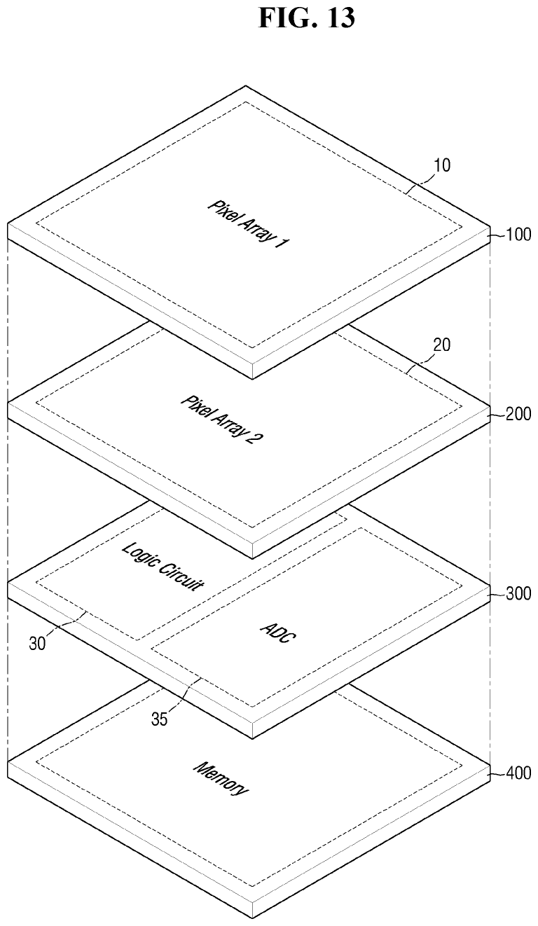

FIG. 13 is a perspective view for three-dimensionally explaining an image sensor according to some embodiments. Referring to FIG. 13, the image sensor according to some embodiments may further include a fourth semiconductor chip 400. In particular, the first semiconductor chip 100, the second semiconductor chip 200, and the third semiconductor chip 300 may be sequentially stacked in a vertical direction. And, the fourth semiconductor chip 400 may be disposed under the third semiconductor chip 300, so that the third semiconductor chip 300 extends between the second semiconductor chip 200 and the fourth semiconductor chip 400.

The fourth semiconductor chip 400 may include a memory device. The fourth semiconductor chip 400 may include, for example, a volatile memory device such as DRAM or SRAM. The fourth semiconductor chip 400 may receive signals from the first semiconductor chip 100 and the second semiconductor chip 200 and process the signals through the memory device. That is, the image sensor including the fourth semiconductor chip 400 may correspond to a four-stack image sensor. Although not illustrated, the fourth semiconductor chip 400 may also include a logic device. That is, in some embodiments, the fourth semiconductor chip 400 may include a memory device and a logic device.

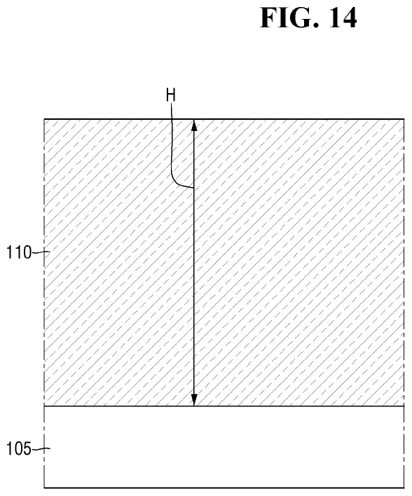

Hereinafter, a method of manufacturing an image sensor according to some embodiments will be described with reference to FIGS. 14 to 20.

FIGS. 14 to 20 are diagrams for explaining a method of manufacturing an image sensor manufactured using a substrate for manufacturing an image sensor according to some embodiments. Referring to FIG. 14, a substrate for manufacturing an image sensor including a substrate layer 105 and an epitaxial layer 110 is provided.

The substrate layer 105 may be the substrate layer of FIG. 1. The epitaxial layer 110 may be the epitaxial layer of FIG. 1. In addition, a part of the epitaxial layer 110 may be the first substrate of FIG. 8, but is not limited thereto.

The substrate layer 105 may be a base substrate. The substrate layer 105 may be a silicon substrate, or may include other materials such as silicon germanium, indium antimonide, lead tellurium compound, indium arsenide, indium phosphide, gallium arsenide, or gallium antimonide.

The substrate layer 105 may be a substrate doped with boron (B). The concentration of boron (B) included in the substrate layer 105 may be 1×10¹⁹ atoms/cm³ or less. The concentration of boron (B) included in the substrate layer 105 may be, for example, 3×10¹⁸ atoms/cm³ or more and 1×10¹⁹ atoms/cm³ or less. Preferably, the concentration of boron (B) contained in the substrate layer 105 may be, for example, 3×10¹⁸ atoms/cm³ or more and 5×10¹⁸ atoms/cm³ or less, but is not limited thereto.

The epitaxial layer 110 may be disposed on the substrate layer 105. The epitaxial layer 110 may be formed through epitaxial growth using the substrate layer 105 as a base substrate, but is not limited thereto.

The epitaxial layer 110 may be an epitaxial layer doped with boron (B). The concentration of boron (B) included in the epitaxial layer 110 may be, for example, 1×10¹⁶ atoms/cm³ or more and 6×10¹⁶ atoms/cm³ or less. Preferably, the concentration of boron (B) included in the epitaxial layer 110 may be 4×10¹⁶ atoms/cm³ or more and 5.5×10¹⁶ atoms/cm³ or less. More preferably, the concentration of boron (B) included in the epitaxial layer 110 may be 5×10¹⁶ atoms/cm³. However, the technical spirit of the present disclosure is not limited thereto.

In some embodiments, the concentration of boron (B) included in the substrate layer 105 is higher than the concentration of boron (B) included in the epitaxial layer 110. For example, the concentration of boron (B) included in the substrate layer 105 may be about 50 times or higher than the concentration of boron (B) included in the epitaxial layer 110, but is not limited thereto.

Since the concentration of boron (B) included in the substrate layer 105 is about 50 times (or higher than) the concentration of boron (B) included in the epitaxial layer 110, the substrate layer 105 and the epitaxial layer 110 may have an etch selectivity. In addition, since the concentration of boron (B) included in the substrate layer 105 is about 50 times (or higher than) the concentration of boron (B) included in the epitaxial layer 110, the critical thickness H of the epitaxial layer 110 may be 10 μm or more.

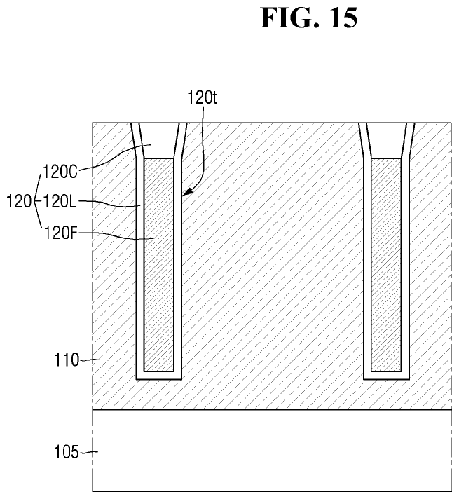

Referring to FIG. 15, the pixel isolation pattern 120 may be formed in the epitaxial layer 110. The pixel isolation pattern 120 may be formed in a pixel isolation trench 120t. The pixel isolation liner layer 120L may be formed along sidewalls and bottom surfaces of the pixel isolation trench. The pixel isolation filling layer 120F may be formed on the pixel isolation liner layer 120L. The pixel isolation capping layer 120C may fill the pixel isolation trench 120t remaining after forming the pixel isolation liner layer 120L and the pixel isolation filling layer 120F.

Although not illustrated, first, a part of the epitaxial layer 110 is etched to form the pixel isolation trench 120t, and the pixel isolation liner layer 120L is formed along sidewalls and bottom surfaces of the pixel isolation trench 120t. Subsequently, the pixel isolation filling layer 120F and the pixel isolation capping layer 120C are formed on the pixel isolation liner layer 120L. However, the technical spirit of the present disclosure is not limited thereto.

In some embodiments, a bottom surface of the pixel isolation trench 120t may be positioned at a level higher than a top surface of the substrate layer 105. That is, a part of the epitaxial layer 110 may be interposed between the pixel isolation pattern 120 and the substrate layer 105.

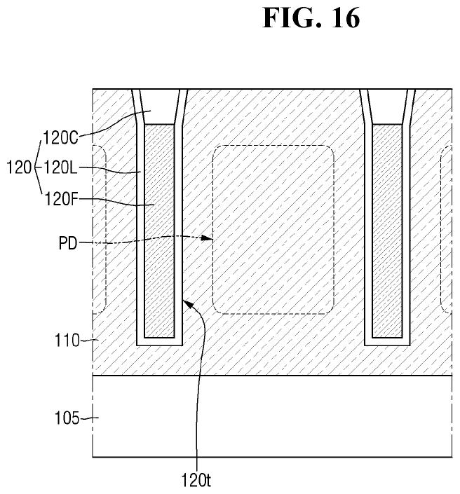

Referring to FIG. 16, the photoelectric conversion layer PD may be formed in the epitaxial layer 110, and may be interposed between the pixel isolation patterns 120. That is, the photoelectric conversion layer PD may be separated from each other by the pixel isolation pattern 120.

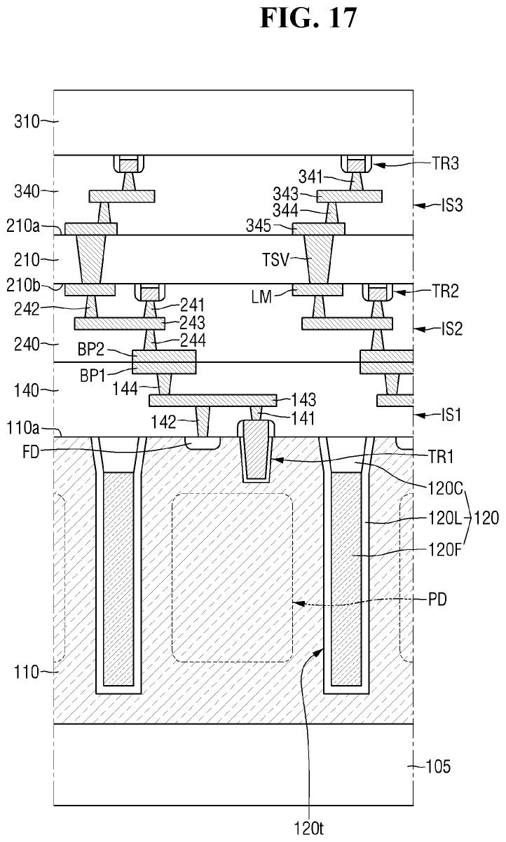

Referring to FIG. 17, the first wiring structure IS1 is formed on the epitaxial layer 110 and the pixel isolation pattern 120. The first wiring structure IS1 may be the same as the first wiring structure IS1 of FIG. 8.

The first wiring structure IS1 may include the first inter inter-wiring insulating layer 140, the first inter-wiring patterns 143, the plurality of contacts 141, 142, and 144, and the bonding pads BP1.

Subsequently, the second substrate 210 and the second wiring structure IS2 may be formed, and the second wiring structure IS2 and the first wiring structure IS1 may be bonded. The second wiring structure IS2 may include the second bonding pads BP2, the plurality of contacts 241, 242, and 244, the second wiring patterns 243, and the landing metal LM.

The second inter-wiring insulating layer 240 and the first inter-wiring insulating layer 140 may be bonded to each other. The second bonding pad BP2 and the first bonding pad BP1 may be bonded to each other.

Subsequently, the through via TSV penetrating the second substrate 210 may be formed. The through via TSV may be connected to the landing metal LM. The through via TSV may extend from the third surface 210a to the fourth surface 210b of the second substrate 210.

Subsequently, the third substrate 310 and the third wiring structure IS3 may be formed, and the second substrate 210 and the third inter-wiring insulating layer 340 may be bonded to each other. The third wiring structure IS3 may include the third inter-wiring insulating layer 340, the plurality of contacts 341 and 344, the third wiring patterns 343, and the pad metals 345. The pad metals 345 and the through via TSV may be electrically connected to each other. Accordingly, the third transistors TR3 and the second transistors TR2 may be electrically connected to each other.

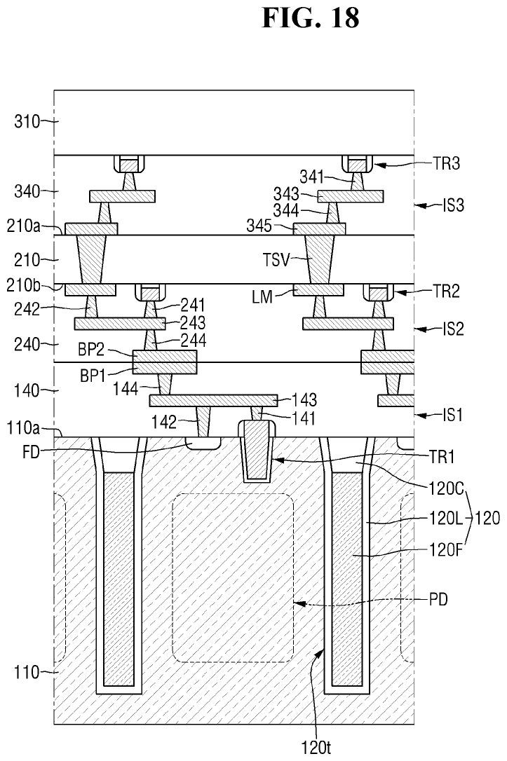

Referring to FIG. 18, the substrate layer 105 may be removed. A wet etching process may be used to remove the substrate layer 105. As described above, the concentration of boron (B) included in the substrate layer 105 is about 50 times or higher than the concentration of boron (B) included in the epitaxial layer 110. Accordingly, the substrate layer 105 and the epitaxial layer 110 may have an etch selectivity with respect to each other. During the wet etching process, the substrate layer 105 may be rapidly removed, but the epitaxial layer 110 is not removed. Accordingly, the substrate layer 105 may be selectively removed. The substrate layer 105 may be removed to expose the surface of the epitaxial layer 110.

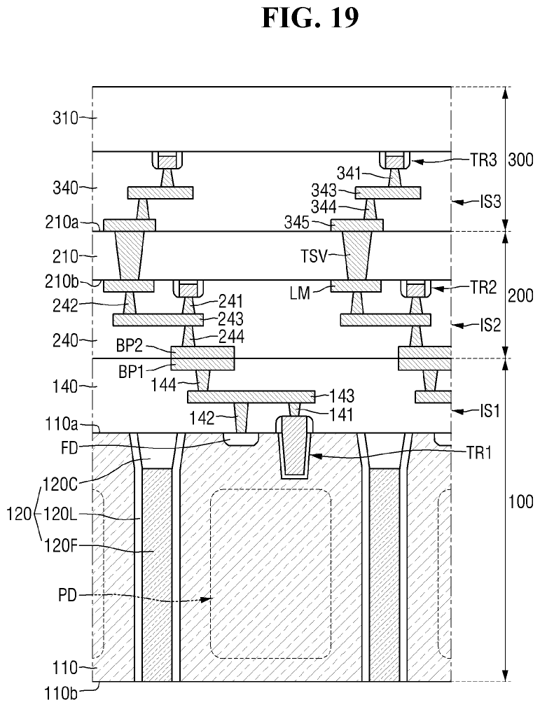

Referring to FIG. 19, a part of the epitaxial layer 110 may be removed to expose the pixel isolation filling layer 120F. The pixel isolation liner layer 120L formed on the bottom surface of the pixel isolation trench 120t may be removed to expose the pixel isolation filling layer 120F. A part of the epitaxial layer 110 may be removed through a wet etching process. A part of the epitaxial layer 110 is removed to form the first substrate 110. The first surface 110a of the first substrate 110 may be on the same plane as the top surface of the pixel isolation capping layer 120C. The second surface 110b of the first substrate 110 may be on the same plane as the bottom surface of the pixel isolation filling layer 120F.

Since a part of the epitaxial layer 110 is removed to form the first substrate 110, the concentration of boron (B) included in the first substrate 110 may be, for example, 1×10¹⁶ atoms/cm³ or more and 6×10¹⁶ atoms/cm³ or less. Preferably, the concentration of boron (B) included in the first substrate 110 may be 4×10¹⁶ atoms/cm³ or more and 5.5×10¹⁶ atoms/cm³ or less. More preferably, the concentration of boron (B) included in the first substrate 110 may be 5×10¹⁶ atoms/cm³. However, the technical spirit of the present disclosure is not limited thereto.

In some embodiments, a separate ion implantation process may not be performed after forming the pixel isolation pattern 120. Accordingly, the concentration of boron (B) included in the first substrate 110 may be constant. For example, as it goes from the sidewall of the pixel isolation pattern 120 toward the photoelectric conversion layer PD, the concentration of boron (B) included in the first substrate 110 may be constant. In addition, as it goes from the first surface 110a of the first substrate 110 toward the second surface 110b, the concentration of boron (B) included in the first substrate 110 may be constant. However, the technical spirit of the present disclosure is not limited thereto.

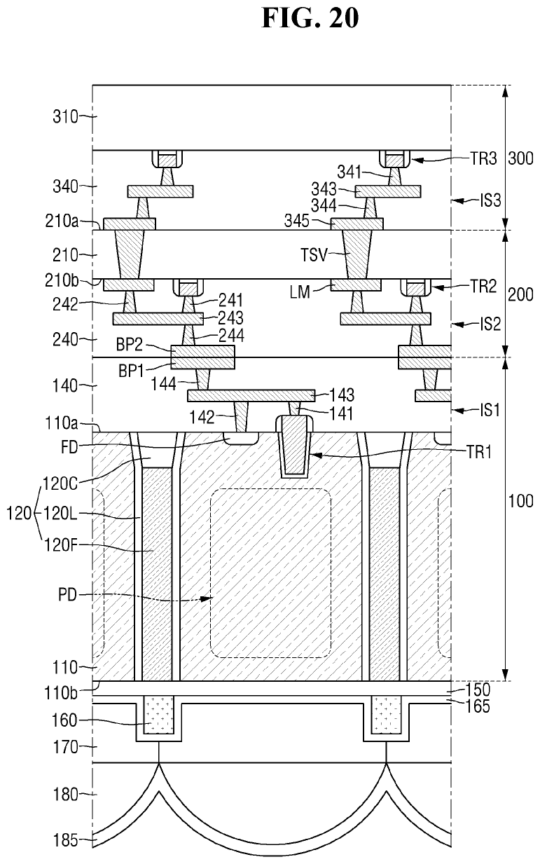

Referring to FIG. 20, the surface insulating layer 150, the grid pattern 160, the first passivation layer 165, the first color filter 170, the microlens 180, and the second passivation layer 185 may be sequentially formed on the second surface 110b of the first substrate 110.

In concluding the detailed description, those skilled in the art will appreciate that many variations and modifications may be made to the preferred embodiments without substantially departing from the principles of the present disclosure. Therefore, the disclosed preferred embodiments of the disclosure are used in a generic and descriptive sense only and not for purposes of limitation.

What is claimed is:

1. An image sensor substrate, comprising:
a semiconductor substrate layer having a boron (B) concentration therein in a range from 3×10¹⁸ cm⁻³ to 1×10¹⁹ cm⁻³; and
a semiconductor epitaxial layer on the substrate layer, said epitaxial layer having a boron (B) concentration therein in a range from 1×10¹⁶ cm⁻³ to 6×10¹⁶ cm⁻³.

2. The substrate of claim 1, wherein the epitaxial layer has a boron (B) concentration therein in a range from 4×10¹⁶ cm⁻³ to 5.5×10¹⁶ cm⁻³.

3. The substrate of claim 1, wherein the epitaxial layer has a boron (B) concentration therein of 5×10¹⁶ cm⁻³.

4. The substrate of claim 1, wherein the concentration of boron (B) in the substrate layer is fifty (50) or more times greater than the concentration of boron (B) in the epitaxial layer.

5. The substrate of claim 1, wherein the epitaxial layer has a thickness of at least 10 μm.

6. An image sensor, comprising:
a first substrate having first and second opposing surfaces thereon and a plurality of unit pixels therein, with each unit pixel including a photoelectric conversion layer, a floating diffusion region, and a transfer transistor electrically connecting the photoelectric conversion layer to the floating diffusion region;
a pixel isolation pattern, which at least partially penetrates the first substrate to thereby define each of the plurality of unit pixels;
a microlens extending on the second surface of the first substrate;
a second substrate on the first surface of the first substrate, said second substrate having a fourth surface that faces the first surface, and a third surface extending opposite the fourth surface; and
a source follower transistor, a select transistor, and a reset transistor having respective terminals electrically connected to the floating diffusion region, adjacent the fourth surface of the second substrate; and
wherein a concentration of boron (B) in the first substrate is in a range from 1×10¹⁶ atoms/cm³ to 6×10¹⁶ atoms/cm³.

7. The image sensor of claim 6, wherein the concentration of boron (B) in the first substrate is in a range from 4×10¹⁶ atoms/cm³ to 5.5×10¹⁶ atoms/cm³.

8. The image sensor of claim 7, wherein the concentration of boron (B) in the first substrate is 5×10¹⁶ atoms/cm³.

9. The image sensor of claim 6, wherein the concentration of boron (B) in the first substrate is substantially uniform in a region between a sidewall of the pixel isolation pattern and the photoelectric conversion layer.

10. The image sensor of claim 6, further comprising:
a first wiring structure, which extends on the first surface of the first substrate and comprises a first inter-wiring insulating layer, and a first wiring pattern in the first inter-wiring insulating layer; and
a second wiring structure, which extends on the fourth surface of the second substrate and comprises a second inter-wiring insulating layer, and a second wiring pattern in the second inter-wiring insulating layer; and
wherein the first inter-wiring insulating layer and the second inter-wiring insulating layer are bonded to each other.

11. The image sensor of claim 10, further comprising a through-via, which at least partially penetrates the second substrate.

12. The image sensor of claim 6, wherein the concentration of boron (B) in the first substrate is substantially uniform in a region between the second surface of the first substrate and the photoelectric conversion layer.

13. The image sensor of claim 6, further comprising:
a third substrate extending on the third surface of the second substrate; and
a plurality of logic circuits configured to control the source follower transistor, the select transistor, and the reset transistor, on the third substrate.

14. The image sensor of claim 13, further comprising a memory device and a logic device disposed under the third substrate.

15. The image sensor of claim 13, further comprising:
a second wiring structure extending on the third surface of the second substrate and comprising a second inter-wiring insulating layer and a second wiring pattern in the second inter-wiring insulating layer; and
a third wiring structure extending on the third substrate and comprising a third inter-wiring insulating layer and a third wiring pattern in the third inter-wiring insulating layer; and
wherein the second inter-wiring insulating layer and the third inter-wiring insulating layer are bonded to each other.

16. An image sensor, comprising:
a first substrate having first and second opposing surfaces thereon;
a plurality of unit pixels, which are each configured to include, in the first substrate, a photoelectric conversion layer, a floating diffusion region, and a transfer transistor electrically connecting the photoelectric conversion layer to the floating diffusion region;
a pixel isolation pattern, which at least partially penetrates the first substrate and defines lateral dimensions of each of the plurality of the unit pixels;
a microlens extending on the second surface of the first substrate;
a second substrate having a fourth surface on the first surface of the first substrate, and a third surface extending opposite the fourth surface; and
a source follower transistor, a select transistor, and a reset transistor, having respective terminals electrically connected to the floating diffusion region, on the fourth surface of the second substrate;
a third substrate extending on the third surface of the second substrate; and
a plurality of logic circuits within the third substrate, which are configured to control the source follower transistor, the select transistor, and the reset transistor;
wherein a concentration of boron (B) in the first substrate is in a range from 4×10¹⁶ atoms/cm³ to 5.5×10¹⁶ atoms/cm³;
wherein the concentration of boron (B) in the first substrate is substantially uniform in a region extending from a sidewall of the pixel isolation pattern toward the photoelectric conversion layer.

17. The image sensor of claim 16, wherein the concentration of boron (B) in the first substrate is substantially uniform in a region extending from the second surface of the first substrate toward the photoelectric conversion layer.

18. The image sensor of claim 16, wherein the concentration of boron (B) in the first substrate is 5×10¹⁶ atoms/cm³.

19. The image sensor of claim 16, further comprising a memory device extending adjacent the third substrate.

20. The image sensor of claim 16, further comprising:
a first wiring structure on the first surface of the first substrate, said first wiring structure comprising a first inter-wiring insulating layer and a first wiring pattern in the first inter-wiring insulating layer; and
a second wiring structure on the third surface of the second substrate, said second wiring structure comprising a second inter-wiring insulating layer and a second wiring pattern in the second inter-wiring insulating layer; and
wherein the first inter-wiring insulating layer and the second inter-wiring insulating layer are bonded to each other.
